(19) United States
(12) Patent Application Publication
(10) Pub. No.: US 2023/0240150 A1
(43) Pub. Date: Jul. 27, 2023

(54) MAGNETIC TUNNEL JUNCTION ELEMENT AND METHOD FOR MANUFACTURING THE SAME

(71) Applicant: TAIWAN SEMICONDUCTOR MANUFACTURING COMPANY, LTD., Hsinchu (TW)

(72) Inventors: Chun-Chi CHEN, Hsinchu (TW); Harry-Hak-Lay CHUANG, Hsinchu (TW); Kuei-Hung SHEN, Hsinchu (TW); Cheng-Wei CHIEN, Hsinchu (TW); Yi-Jen HUANG, Hsinchu (TW)

(73) Assignee: TAIWAN SEMICONDUCTOR MANUFACTURING COMPANY, LTD., Hsinchu (TW)

(21) Appl. No.: 17/584,135

(22) Filed: Jan. 25, 2022

(51) Int. Cl. H01L 43/02; H01L 27/22; H01L 43/12; H01F 10/32

(52) U.S. Cl. CPC H01L 43/02; H01L 27/222; H01L 43/12; H01F 10/3286; H01L 43/10

(57) ABSTRACT

A magnetic tunnel junction (MTJ) element includes a reference layer, a tunnel barrier layer, a free layer, and a dusting layer. The reference layer has a fixed magnetic orientation. The tunnel barrier layer is disposed on the reference layer, and includes an insulating material. The free layer has a changeable magnetic orientation, and includes a first surface and a second surface. The second surface is disposed to confront the tunnel barrier layer and opposite to the first surface. The dusting layer is formed on one of the first and second surfaces of the free layer, and includes a non-magnetic metal. Another aspect of the MTJ element, and a method for manufacturing the MTJ element are also disclosed.

### BACKGROUND

Magnetic tunnel junction (MTJ) is a core component in several applications including read-heads of hard disk drives, sensors and magneto-resistive random-access memory (MRAM). Among them, MRAM is an emerging non-volatile memory that is advantageous in terms of ultra-low power consumption and easy integration with logic circuit. The discovery of perpendicularly magnetized MTJ (p-MTJ) has attracted more attention than MTJ with in-plane magnetization, because the p-MTJ relies on interfacial perpendicular magnetic anisotropic (PMA) instead of magneto-static shape anisotropy, such that the size of p-MTJ can be further reduced while retaining sufficient thermal stability. Thermal stability, which is positively related to PMA, and tunneling magnetoresistance (TMR) ratio are key parameters for evaluating the performance of the p-MTJ. However, strong PMA and high TMR ratio are not easy to be achieved simultaneously during optimization of the p-MTJ. Hence, p-MTJ is continuously developed to achieve a high thermal stability and a high TMR ratio in order to obtain good data retention and read margin of memory cells in non-volatile magnetic memory.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a sectional view of a semiconductor structure with a plurality of magnetic devices in accordance with some embodiments.

FIG. 2 illustrates a partial enlarged view of one of the magnetic devices shown in FIG. 1 in accordance with some embodiments.

FIG. 3 is a schematic view illustrating a magnetic tunnel junction (MTJ) element in a bottom spin valve configuration, in which a dusting layer is interposed between a tunnel barrier layer and a free layer in accordance with some embodiments.

FIG. 4 is a view similar to that of FIG. 3, but illustrating the MTJ element in a top spin valve configuration in accordance with some embodiments.

FIG. 5 is a scatter plot of coercive field (Hc) versus tunneling magnetoresistance (TMR) ratio for samples of the MTJ element shown in FIG. 3 and baseline samples of a baseline MTJ element in accordance with some embodiments.

FIG. 6 illustrates a schematic view of a MTJ element in a bottom spin valve configuration, in which a dusting layer is interposed between the free layer and a capping layer in accordance with some embodiments.

FIG. 7 is a view similar to that of FIG. 6, but illustrating the MTJ element in a top spin valve configuration in accordance with some embodiments.

FIG. 8 is an energy-dispersive X-ray spectroscopy (EDS) line scan illustrating material composition for a sample of the MTJ element shown in FIG. 6 and a baseline sample of a baseline MTJ element in accordance with some embodiments.

FIG. 9 is a scatter plot of Hc versus TMR ratio for samples of the MTJ element shown in FIG. 6 and baseline samples of a baseline MTJ element in accordance with some embodiments.

FIG. 10 is a graph illustrating relationship of Hc and resistance-area product (RA) versus a thickness of the dusting layer for samples of the MTJ element shown in FIG. 6 in accordance with some embodiments.

FIG. 11 illustrates scatter plots of canting versus critical dimension (CD) and those of canting versus electrical properties for samples of the MTJ element shown in FIG. 6 and baseline samples of a baseline MTJ element in accordance with some embodiments.

FIG. 12 is a graph illustrating relationship of magnetic and electrical properties versus a thickness of molybdenum (Mo) for samples of the MTJ element shown in FIG. 6 in accordance with some embodiments.

FIG. 13 is a scatter plot of Hc versus TMR ratio for samples of two of the MTJ elements shown in FIG. 6 which includes the dusting layers having different materials in accordance with some embodiments.

FIG. 14 illustrates scatter plots of Hc versus electrical properties for samples of the two MTJ elements shown in FIG. 6 which includes the dusting layers having different materials in accordance with some embodiments.

FIG. 15 is a schematic view of a MTJ element including two dusting layers in a bottom spin valve configuration in accordance with some embodiments.

FIG. 16 is a view similar to that of FIG. 15, but illustrating the MTJ element in a top spin valve configuration in accordance with some embodiments.

FIG. 17 is a flow diagram illustrating a method for manufacturing the MTJ element in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “upper,” “lower,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure is directed to a magnetic tunnel junction (MTJ) element with improved thermal stability and a method for manufacturing the same. The MTJ element may be incorporated in various magnetic devices, such as magneto-resistive random-access memory (MRAM), sensor, biosensor, spin-transfer torque MRAM (STT-MRAM), spin-orbit torque MRAM (SOT-MRAM), spintronic devices (e.g., spin-torque oscillator (STO) or microwave-assisted magnetic recording (MAMR)), or various design of perpendicular magnetic anisotropic (PMA) spin valve, but are not limited thereto. Other suitable applications for the MTJ element are within the contemplated scope of disclosure. Furthermore, the dimension of the MTJ element is able to be adjusted, so that the MTJ element is permitted to be integrated in varieties of semiconductor technology nodes or generations, such as 65 nm, 85 nm, but is not limited thereto.

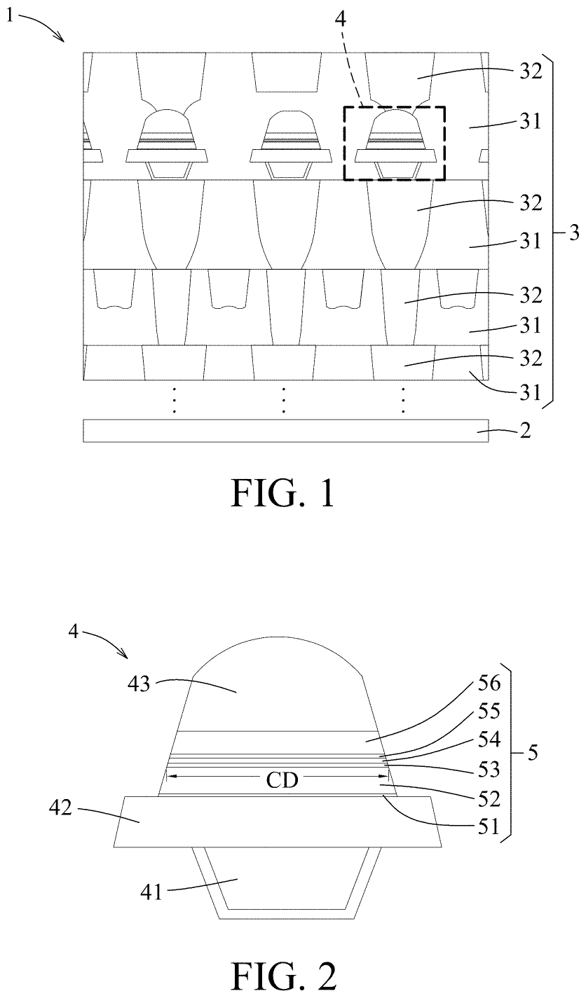

FIG. 1 illustrates a semiconductor structure 1 in accordance with some embodiments. The semiconductor structure 1 includes a semiconductor substrate 2, an interconnect structure 3 and a plurality of magnetic devices 4. The interconnect structure 3 is formed on the semiconductor substrate 2, and includes a plurality of dielectric layers 31 and a plurality of metal interconnecting layers 32, each of which is embedded in a corresponding one of the dielectric layers 31. Each of the magnetic devices 4 may be independently positioned between and electrically connected to any two sequential ones of the metal interconnecting layers 32, for example, N^{th} metal interconnecting layers and (N+1)^{th} metal interconnecting layers, where N is an integer greater than or equal to one. FIG. 2 illustrates a partial enlarged view of one of the magnetic devices 4 shown in FIG. 1 in accordance with some embodiments.

In some embodiments, as shown in FIG. 1, the interconnect structure 3 includes four of the dielectric layers 31 and four of the metal interconnecting layers 32. In certain embodiments, the number and configuration of the dielectric layers 31 and the metal interconnecting layers 32 can be varied according to the layout design of the semiconductor structure 1.

In some embodiments, the semiconductor substrate 2 may be made of an elemental semiconductor material, or an alloy semiconductor material, but is not limited thereto. Other suitable materials for the semiconductor substrate 2 are within the contemplated scope of disclosure. In some embodiments, a peripheral circuit (not shown) may be formed over the semiconductor substrate 2, and may include active devices (for example, transistors, or the like), passive devices (for example, capacitors, resistors, or the like), decoders, amplifiers, and combinations thereof. In some embodiments, through the interconnecting layers 32, each of the magnetic devices 4 can be electrically connected to the peripheral circuit or other suitable devices located above the magnetic devices 4. Other suitable peripheral circuits and routing for controlling the magnetic devices 4 are within the contemplated scope of disclosure.

In some embodiments, as shown in FIG. 2, each of the magnetic devices 4 is configured as an STT-MRAM structure, and has an MTJ element 5 which can be switchable between a parallel (P) state or an antiparallel (AP) state due to a tunneling magneto-resistance (TMR) effect. The STT-MRAM structure 4 includes a top electrode 43, a bottom electrode 42, a bottom electrode via 41 disposed beneath the bottom electrode 42, and the MTJ element 5 interposed between the top electrode 43 and the bottom electrode 42. The top electrode 43 and the bottom electrode via 41 of the STT-MRAM structure 4 are electrically coupled to two sequential ones of the metal interconnecting layers 32 (see FIG. 1), and thus the STT-MRAM structure 4 can be connected to the peripheral circuit or other suitable devices. In some embodiments, the number of the STT-MRAM structures 4 can be varied according to the design for the memory size of the semiconductor structure 1 (see FIG. 1). In some embodiments, the semiconductor structure 1 may include millions of the STT-MRAM structures 4 that are arranged in rows and columns.

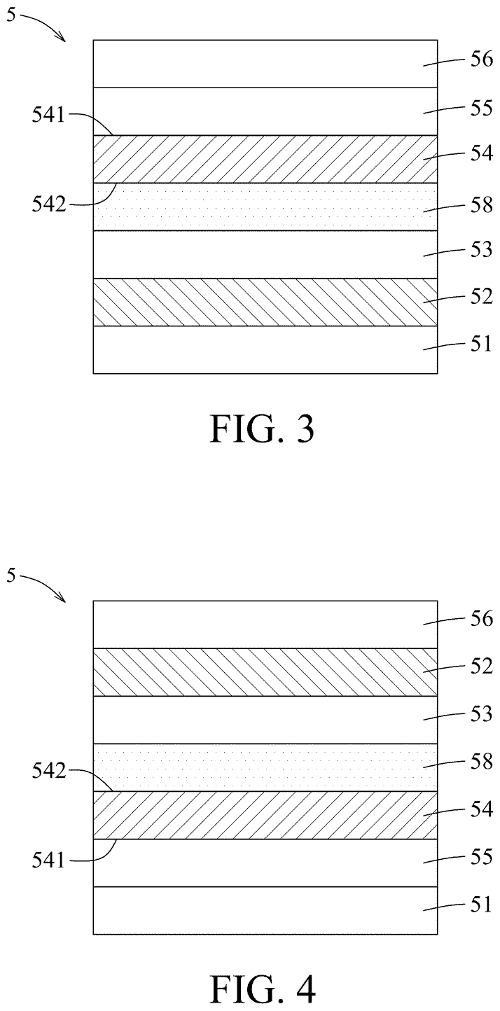

FIG. 3 is a schematic view illustrating the MTJ element 5 shown in FIG. 2 in a bottom spin valve configuration in accordance with some embodiments. FIG. 4 is a view similar to that of FIG. 3, but illustrating the MTJ element 5 in a top spin valve configuration in accordance with some embodiments. The MTJ element 5 includes a reference layer (i.e., pin layer) 52, a tunnel barrier layer 53 disposed on the reference layer 52, a free layer 54 disposed on the tunnel barrier layer 53, and a dusting layer 58. The free layer 54 has a first surface 541 and a second surface 542 which confronts the tunnel barrier layer 53 and which is opposite to the first surface 541. The reference layer 52 has a fixed magnetic orientation, and the free layer 54 has a changeable magnetic orientation (e.g., parallel or antiparallel to the magnetic orientation of the reference layer 52) so as to provide the P state or the AP state. The dusting layer 58 is formed on one of the first and second surfaces 541, 542 of the free layer 54. In some embodiments, as shown in FIGS. 3 and 4, the dusting layer 58 is interposed between the tunnel barrier layer 53 and the free layer 54.

The tunnel barrier layer 53 includes a first insulating material for electrons to tunnel therethrough. In some embodiments, the first insulating material of the tunnel barrier layer 53 includes oxide, nitride, or oxynitride, or combinations thereof, so as to induce a spin dependent tunneling effect between the reference layer 52 and the free layer 54. In some embodiments, the first insulating material of the tunnel barrier layer 53 includes, for example, but is not limited to, magnesium oxide (MgO), aluminum oxide (AlOₓ), silicon oxide (SiOₓ), titanium oxide (TiOₓ), tantalum oxide (TaOₓ), chromium oxide (CrOₓ), hafnium oxide (HfOₓ), zinc oxide (ZnO), or combinations thereof. Other suitable materials for the tunnel barrier layer 53 are within the contemplated scope of disclosure. In some embodiments, the tunnel barrier layer 53 is made of MgO having a (001) texture. In some embodiments, the tunnel barrier layer 53 has a thickness ranging from about 1 Å to about 30 Å.

In some embodiments, the reference layer 52 includes a first ferromagnetic material, such as cobalt (Co), iron (Fe), nickel (Ni), cobalt-iron alloy (CoFe), cobalt-iron-nickel alloy (CoFeNi), cobalt-boron alloy (CoB), iron-boron alloy (FeB), cobalt-iron-boron alloy (CoFeB), or combinations thereof. In some embodiments, the reference layer 52 may be formed as a single layer structure or a multi-layered structure, such as (Co/X)ₙ, where X may be Ni, platinum (Pt), palladium (Pd), etc., and n is an integer greater than two. In some embodiments, the reference layer 52 exhibits perpendicular magnetic anisotropy (PMA) with a fixed magnetic orientation in a direction perpendicular to the plane of the semiconductor substrate 2. In some embodiments, the reference layer 52 further includes a non-magnetic coupling layer (not shown), such as ruthenium (Ru) or iridium (Ir), which is stacked with the ferromagnetic material and which serves as a moment diluting layer. In some embodiments, the reference layer 52 further includes a transition layer (not shown) which is in contact with the tunnel barrier layer 53 so as to induce or enhance interfacial PMA of the reference layer 52 by forming, for example, but not limited to, a ferromagnetic metal/oxide interface. Other suitable materials for the reference layer 52 are within the contemplated scope of disclosure. In some embodiments, the reference layer 52 has a thickness ranging from about 30 Å to about 160 Å.

In some embodiments, the free layer 54 includes a second ferromagnetic material, such as Fe, Co, Ni, CoFe, CoB, FeB, CoFeB, cobalt-iron-nickel-boron alloy (CoFeNiB), or combinations thereof. In some embodiments, the free layer 54 may be formed as a single layer structure or a multi-layered structure having alternatively stacked ferromagnetic and non-magnetic sub-layers. In some embodiments, the free layer 54 has a thickness ranging from about 10 Å to about 30 Å. In some embodiments, the tunnel barrier layer 53 and the free layer 54 together induce an interfacial PMA by forming electronic bonds between the second ferromagnetic material (e.g., CoFeB) and the first insulating material (e.g., MgO), for example, an iron-oxygen (Fe—O) bond (i.e., a bonding between an iron ion in the free layer 54 and an oxygen ion in the tunnel barrier layer 53).

The dusting layer 58 includes a non-magnetic metal. In some embodiments, the non-magnetic material of the dusting layer 58 includes molybdenum (Mo), tungsten (W), or a combination thereof. In some embodiments, the dusting layer 58 has a predetermined thickness to permit the interfacial PMA to be established between the tunnel barrier layer 53 and the free layer 54. That is to say, although the dusting layer 58 is interposed between the tunnel barrier layer 53 and the free layer 54, the dusting layer 58 does not completely separate the tunnel barrier layer 53 from the free layer 54, and a plurality of interfacial regions (not shown) are formed between the tunnel barrier layer 53 and the free layer 54 for inducing the interfacial PMA. In some embodiments, the dusting layer 58 has a body center cubic (bcc) crystalline structure, while in some alternative embodiments, the dusting layer 58 may have an amorphous structure. It is known to those in the art that there are several annealing steps performed at a temperature of up to 400° C. for several hours in back-end-of-line (BEOL) processes, and thus impurities (e.g., boron from the reference layer 52 or the free layer 54) will be inevitably diffused among the layers of the MTJ element 5 during annealing steps. Without being limited to any one theory, it is considered that less impurities at the interfacial regions between the tunnel barrier layer 53 (for example, MgO) and the free layer 54 (for example, CoFeB) may enable more Fe—O bonds to be established, thereby inducing a higher interfacial PMA. In the disclosure, it is believed that the dusting layer 58 serves as a diffusion barrier that is able to reduce impurities at the interfacial regions between the tunnel barrier layer 53 and the free layer 54 because vacancies between the second ferromagnetic material and the first insulating material have been occupied by the non-magnetic metal (i.e., Mo and/or W atoms), thereby enhancing the interfacial PMA effect of the free layer 54. The predetermined thickness of the dusting layer 58 has an optimizable value. Excess thickness of the first dusting layer 58 may interfere Fe—O bonds to be established, and causes reduction of interfacial PMA. On the contrary, if the dusting layer 58 is too thin, the dusting layer 58 may loss its function as a barrier layer. In some embodiments, the predetermined thickness of the dusting layer 58 is greater than 0 Å and less than about 3 Å. In some embodiments, when the dusting layer 58 is made of W, the predetermined thickness of the dusting layer 58 may range from about 0.3 Å to about 1.1 Å. In some embodiments, when the dusting layer 58 is made of Mo, the predetermined thickness of the dusting layer 58 may range from about 0.73 Å to about 2.64 Å.

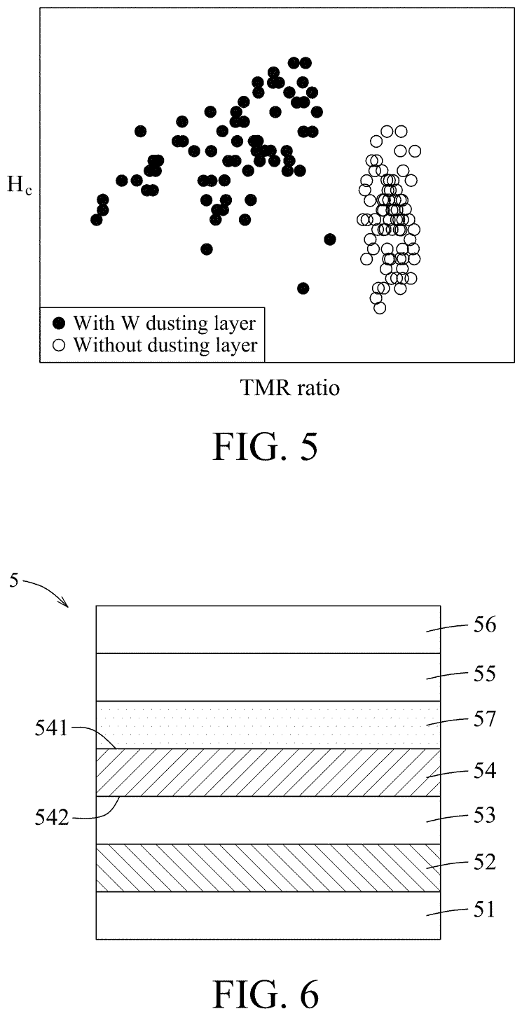

FIG. 5 illustrates a scatter plot of coercive field (Hc) versus TMR ratio for samples of the MTJ element 5 shown in FIG. 3 and baseline samples of a baseline MTJ element in accordance with some embodiments. The dusting layer 58 for the samples of the MTJ element 5 shown in FIG. 3 is made of W (hereinafter referred to as a W dusting layer), and the baseline MTJ element has a structure similar to that of the MTJ element 5 shown in FIG. 3 except that the dusting layer 58 is absent. In FIG. 5, the coercive field (Hc) represents interfacial PMA strength and can be observed from plots of the resistance of the MTJ element versus applied magnetic field (i.e., resistance-magnetic field (R-H) loops). An applied magnetic field for switching the resistance of the MTJ element from R_{AP} (the resistance at the AP state) to R_{P} (the resistance at the AP state) is referred to as Hc. In FIG. 5, the TMR ratio is obtained from an equation of (R_{AP}−R_{P})/R_{P}×100%. It can be seen that the MTJ element 5 with the W dusting layer has a higher He value compared with the baseline MTJ element without the dusting layer 58, while the MTJ element 5 has a lower TMR ratio than that of the baseline MTJ element. In some embodiments, the He value of the MTJ element 5 is larger than that of the baseline MTJ element by about 100 Oe to about 350 Oe, and the TMR ratio difference between the MTJ element 5 and the baseline MTJ element ranges from about 30% to about 80%.

In some embodiments, as shown in FIGS. 3 and 4, the MTJ element 5 further includes a capping layer 55 disposed on the first surface 541 of the free layer 54 opposite to the dusting layer 58. In some embodiments, the capping layer 55 includes a second insulating material (for example, but not limited to, an oxide material), so as to further increase interfacial PMA effect of the free layer 54 by forming, for example, but not limited to, a ferromagnetic metal/oxide interface. Since the second insulating material is similar to the first insulating material of the tunnel barrier layer 53, details of the possible materials for the capping layer 55 are omitted for the sake of brevity. In some embodiments, the capping layer 55 has a thickness ranging from about 1 Å to about 30 Å.

In some embodiments, the MTJ element 5 further includes a seed layer 51 and a buffer layer 56, as shown in FIGS. 3 and 4. The seed layer 51 is optional, but is often used to facilitate uniform crystal growth of a multi-layered stack formed thereon. The buffer layer 56 is optional, but is often used to protect the multi-layered stack disposed therebeneath during fabrication of peripheral metal routing. In the case of the MTJ element 5 in a bottom spin valve configuration, the reference layer 52, the tunnel barrier layer 53, the dusting layer 58, the free layer 54, the capping layer 55, and the buffer layer 56 are sequentially disposed on the seed layer 51, as shown in FIG. 3. Alternatively, in the case of the MTJ element 5 in a top spin valve configuration, the capping layer 55, the free layer 54, the dusting layer 58, the tunnel barrier layer 53, the reference layer 52, and the buffer layer 56 are sequentially disposed on the seed layer 51, as shown in FIG. 4.

In some embodiments, the seed layer 51 includes Ni, Ru, Pt, tantalum (Ta), chromium (Cr), nitride thereof, alloy thereof, or combinations thereof. In some embodiments, the seed layer 51 may be formed as a single layer structure or a multi-layered structure having a plurality of sub-layers. In some embodiments, the sub-layers of the seed layer 51 may be an amorphous film, a crystalline film, or a combination thereof. Other suitable materials or configuration for the seed layer 51 are within the contemplated scope of disclosure. In some embodiments, the seed layer 51 has a thickness ranging from about 30 Å to about 100 Å.

In some embodiments, the buffer layer 56 includes Ru, Ta, Mo, alloy thereof, or combinations thereof. In some embodiments, the buffer layer 56 may be formed as a single layer structure or a multi-layered structure. Other suitable materials or configuration for the buffer layer 56 are within the contemplated scope of disclosure. In some embodiments, the buffer layer 56 has a thickness ranging from about 30 Å to about 100 Å.

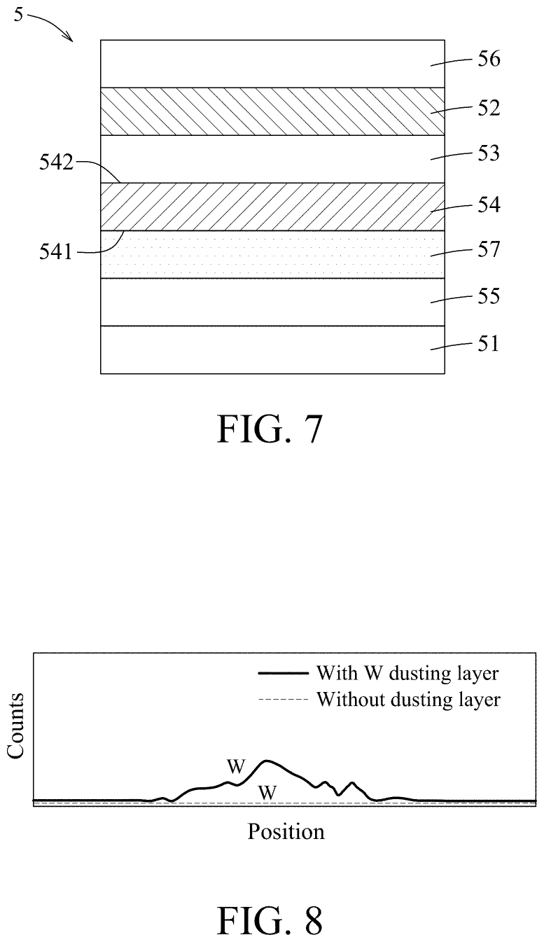

FIGS. 6 and 7 respectively illustrate the MTJ element 5 in a bottom spin valve configuration and a top spin valve configuration in accordance with other embodiments that are respectively similar to those shown in FIG. 3 and FIG. 4, except that the dusting layer 58 is omitted and a dusting layer 57 is interposed between the free layer 54 and the capping layer 55. Since the materials and thickness of the dusting layer 57 are similar to those of the dusting layer 58 described above, and since the seed layer 51, the reference layer 52, the tunnel barrier layer 53, the free layer 54, the capping layer 55, and the buffer layer 56 are similar to those as described above, details thereof are omitted for the sake of brevity. In this case, it is believed that an interfacial PMA between the free layer 54 and the capping layer 55 may be enhanced.

FIG. 8 is an energy-dispersive X-ray spectroscopy (EDS) line scan illustrating material composition for a sample of the MTJ element 5 shown in FIG. 6 and a sample of a baseline MTJ element. For the EDS analysis, the dusting layer 57 is made of W, and the baseline MTJ element is similar to the MTJ element 5 shown in FIG. 6 but without the dusting layer 57. It can be seen that the W signal of the dusting layer 57 in the MTJ element 5 shown in FIG. 6 is detected and identified in EDS analysis, while the W signal of the baseline MTJ element is not observed. Similarly, it is anticipated that the W signal of the dusting layer 58 in the MTJ element shown in FIG. 3 may be detected and identified as well.

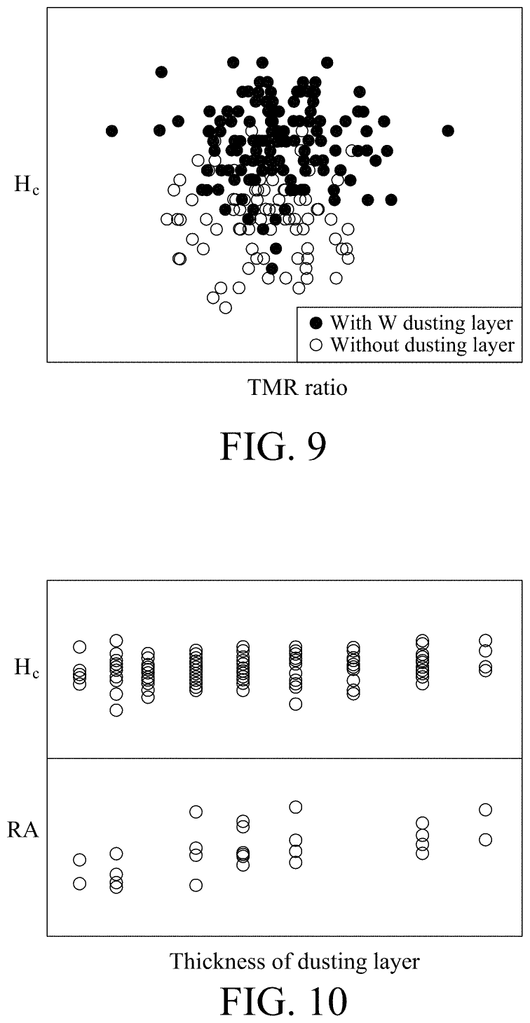

FIG. 9 illustrates a scatter plot of Hc versus TMR ratio for samples of the MTJ element 5 shown in FIG. 6 and baseline samples of a baseline MTJ element. The dusting layer 57 for the samples of the MTJ element 5 shown in FIG. 6 is made of W (hereinafter referred to as a W dusting layer), and the baseline MTJ element has a structure similar to that of the MTJ element 5 shown in FIG. 6 but without the dusting layer 57. The Hc value and the TMR ratio in FIG. 9 are obtained in ways similar to those described in relation to FIG. 5, and the details thereof are omitted for the sake of brevity. It can be seen that the MTJ element 5 with the W dusting layer has a higher Hc value than that of the baseline MTJ element, and has a TMR ratio similar to that of the baseline MTJ element. In some embodiments, the Hc value of the MTJ element 5 is larger than that of the baseline MTJ element by about 200 Oe to about 400 Oe, and no distinguishable TMR ratio difference is found between the MTJ element 5 and the baseline MTJ element.

FIG. 10 is a graph illustrating relationship of Hc and resistance-area product (RA) versus a thickness of the dusting layer 57 for samples of the MTJ element 5 shown in FIG. 6 in accordance with some embodiments. The dusting layer 57 for the samples of the MTJ element 5 shown in FIG. 6 is made of W (hereinafter referred to as a W dusting layer). It can be seen that the Hc value slightly increases with increasing thickness of the W dusting layer as long as interfacial PMA is not adversely affected. In addition, the RA value slightly increases with increasing thickness of the W dusting layer. It is noted that the RA value may be varied with applications of final products.

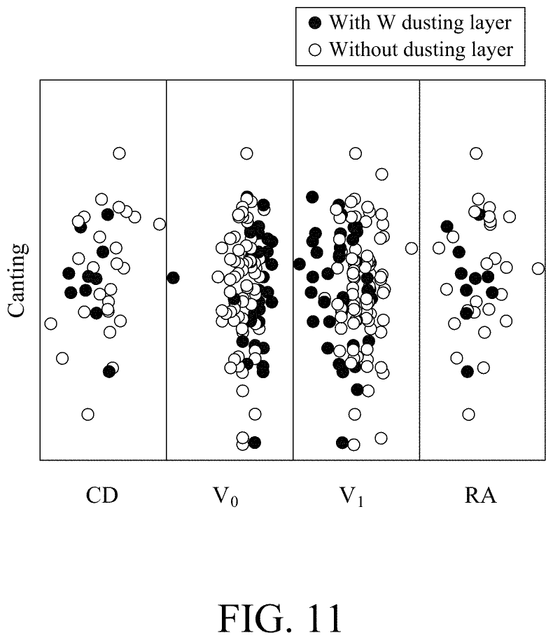

FIG. 11 illustrates scatter plots of canting versus critical dimension (CD) and several electrical properties for samples of the MTJ element 5 shown in FIG. 6 and baseline samples of a baseline MTJ element. The dusting layer 57 for the samples of the MTJ element 5 shown in FIG. 6 is made of W (hereinafter referred to as a W dusting layer), and the baseline MTJ element has a structure similar to that of the MTJ element 5 shown in FIG. 6 but without the dusting layer 57. The canting represents coercivity of the reference layer 52, and is obtained by an equation of R_{AP(H>Hc)}/R_{AP(H=0 Oe)}, where H represents the applied magnetic field and Hc represents the coercive field. The CD is a width of the tunnel barrier layer 53 in a cross-sectional view, as shown in FIG. 2. Electrical properties to be analyzed include a write voltage (V₀) that can be applied to switch the MTJ element 5 to the P state, a write voltage (V₁) that can be applied to switch the MTJ element 5 to the AP state, and the RA as mentioned above. It can be seen that the CD of the tunnel barrier layer 53, the canting of the reference layer 52 and the RA value of the MTJ element 5 are not significantly affected by interposition of the W dusting layer. The values of V₀ and V₁ change slightly but the difference thereof are almost negligible.

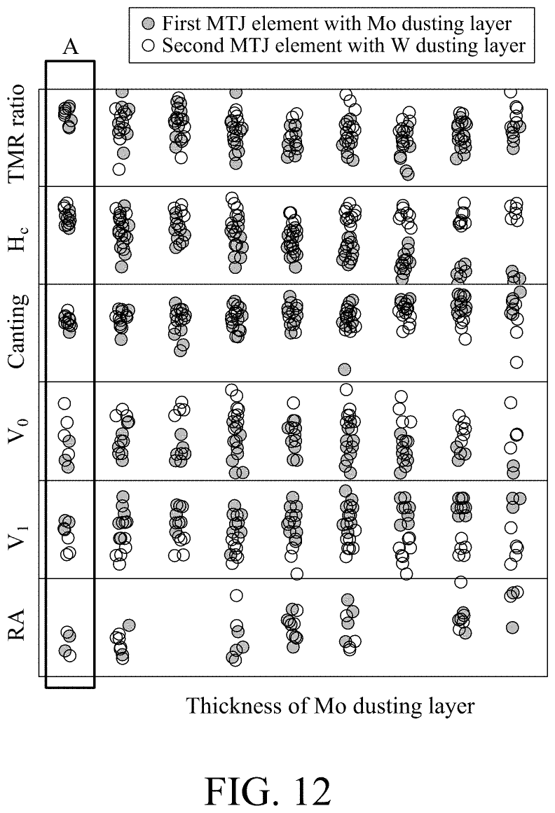

FIG. 12 is a graph illustrating relationship of magnetic and electrical properties versus a thickness of a dusting layer for sample groups of a first MTJ element in accordance with some embodiment. In FIG. 12, the same magnetic and electrical properties for samples of a second MTJ element are also shown. Each of the first and second MTJ elements has a configuration similar to that of the MTJ element 5 shown in FIG. 6. The dusting layers 57 for different sample groups of the first MTJ element have different thickness, and are made of Mo (hereinafter referred to as a Mo dusting layer), while the dusting layers 57 for the samples of the second MTJ element have a fixed thickness and are made of W (hereinafter referred to as a W dusting layer). The magnetic and electrical properties to be analyzed include TMR ratio and values of Hc, canting, V₀, V₁, and RA (the definitions thereof are as described above). It can be seen that the Hc value and TMR ratio increase as the thickness of the Mo dusting layer decreases. The canting of the reference layer 52 slightly increases with increased thickness of the Mo dusting layer. The values of V₀ and V₁ of the first MTJ element slightly decrease with increased thickness of the Mo dusting layer. The RA value of the first MTJ element is not significantly changed with the change in thickness of the Mo dusting layer. Furthermore, it can be observed that the first and second MTJ elements may have similar electrical and magnetic properties when the Mo dusting layer has a first thickness (see frame A shown in FIG. 12). In some embodiments, the first thickness of the Mo dusting layer is less than the fixed thickness of the W dusting layer. Based on the above, it can be concluded that the first MTJ element with the Mo dusting layer may have a higher Hc than that of the baseline MTJ element without the dusting layer 57.

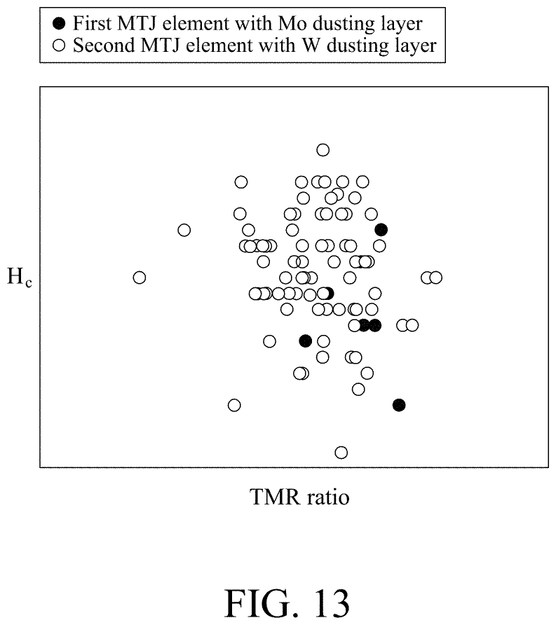

FIG. 13 illustrates a scatter plot of Hc versus TMR ratio for samples of the first MTJ element with the Mo dusting layer and samples of the second MTJ element with the W dusting layer in accordance with some embodiments. It can be seen that the first MTJ element has Hc and TMR ratio similar to those of the second MTJ element.

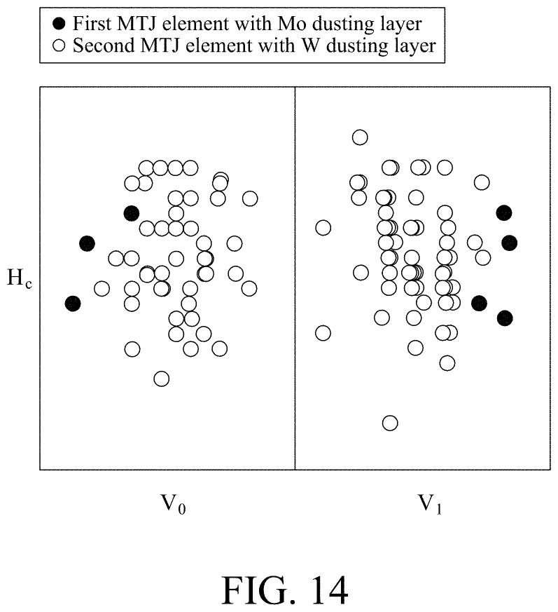

FIG. 14 illustrates a scatter plot of Hc versus V₀ and V₁ for samples of the first MTJ element with the Mo dusting layer and samples of the second MTJ element with the W dusting layer in accordance with some embodiments. It can be seen that the first MTJ element has relatively lower V₀ and V₁ than those of the second MTJ element.

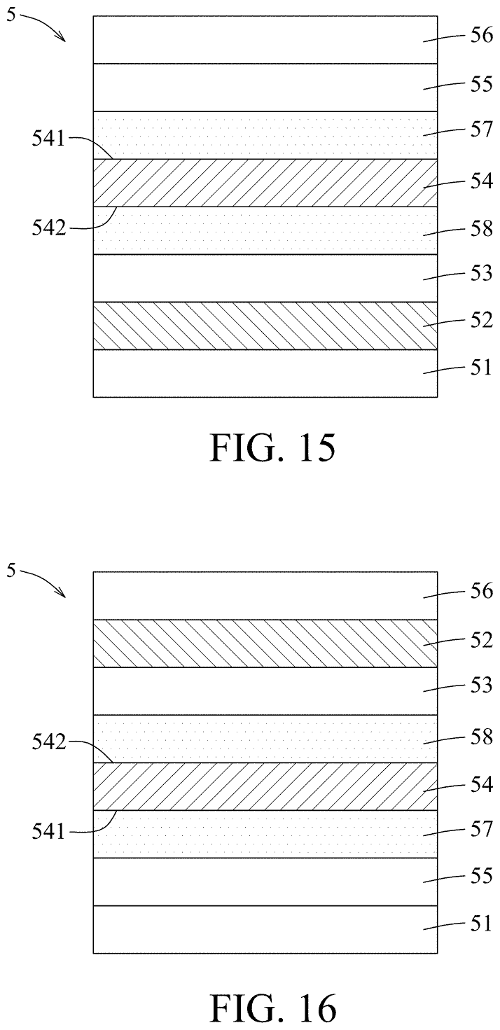

FIG. 15 is a schematic view of a MTJ element 5 in a bottom spin valve configuration in accordance with some embodiment. FIG. 16 is a view similar to that of FIG. 15, but illustrating the MTJ element 5 in a top spin valve configuration in accordance with some embodiments. The MTJ element 5 shown in FIGS. 15 and 16 is similar to those shown in FIGS. 3 to 4 and 6 to 7, except that the MTJ element 5 in FIGS. 15 and 16 have both the dusting layers 57 and 58.

In some alternative embodiments, the MTJ element 5 may further include additional features, and/or some features present in the MTJ element 5 may be modified, replaced, or eliminated without departure from the spirit and scope of the present disclosure.

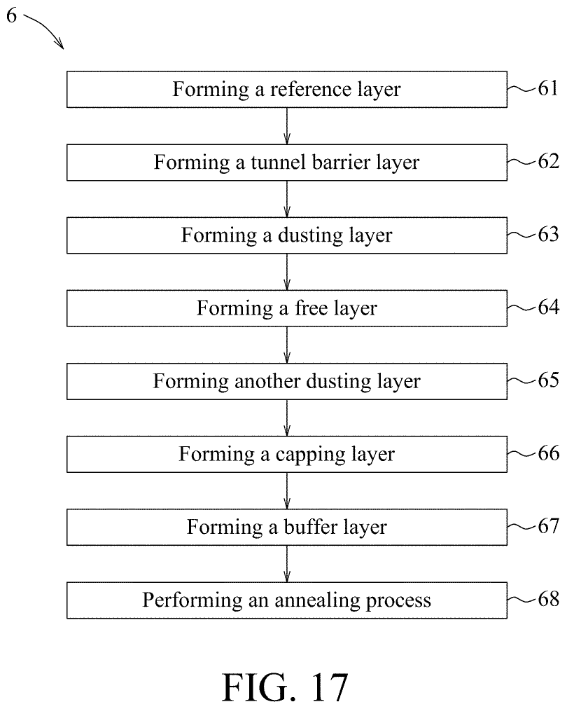

FIG. 17 is a flow diagram illustrating a method 6 for manufacturing a MTJ element, for example, but not limited to, the MTJ element 5, as shown in FIG. 15, in accordance with some embodiments. The method 6 for manufacturing the MTJ element 5 includes steps 61 to 68.

In step 61, the reference layer 52 is formed on the seed layer 51 using a deposition process, such as physical vapor deposition (PVD), molecular beam epitaxy (MBE), pulsed laser deposition (PLD), and electron beam physical vapor deposition (EBPVD). Other suitable techniques for forming the reference layer 52 are within the contemplated scope of disclosure.

In step 62, the tunnel barrier layer 53 is formed on the reference layer 52 using, for example, a deposition process similar to those mentioned in step 61. Other suitable techniques for forming the tunnel barrier layer 53 are within the contemplated scope of disclosure.

In step 63, the dusting layer 58 is formed on the tunnel barrier layer 53 using, for example, a deposition process similar to those mentioned in step 61. In some embodiments, the dusting layer 58 is formed in a PVD chamber, in which a PVD target may be Mo, W, or a combination thereof, and in which a carrier gas (e.g., argon, nitrogen, helium, or the like) for generation of plasma has a flow rate ranging from about 0 sccm to about 1000 sccm. Other suitable techniques for forming the dusting layer 58 are within the contemplated scope of disclosure.

In step 64, the free layer 54 is formed on the dusting layer 58 using, for example, a deposition process similar to those mentioned in step 61. Other suitable techniques for forming the free layer 54 are within the contemplated scope of disclosure.

In step 65, the dusting layer 57 is formed on the free layer 54 using, for example, a deposition process similar to those mentioned in step 63. Other suitable techniques for forming the dusting layer 57 are within the contemplated scope of disclosure.

In step 66, the capping layer 55 is formed on the dusting layer 57 using, for example, a deposition process similar to those mentioned in step 61. Other suitable techniques for forming the capping layer 55 are within the contemplated scope of disclosure.

In step 67, the buffer layer 56 is formed on the capping layer 55 using, for example, a deposition process similar to those mentioned in step 61. Other suitable techniques for forming the buffer layer 56 are within the contemplated scope of disclosure.

In step 68, an annealing process is performed. In some embodiments, the annealing process is performed at a temperature ranging from about 300° C. to about 500° C. (for example, about 400° C.).

Details regarding the seed layer 51, the reference layer 52, the tunnel barrier layer 53, the free layer 54, the capping layer 55, the buffer layer 56, and the dusting layers 57, 58 are similar to those as described above, and thus details thereof are omitted for the sake of brevity.

In some embodiments, some steps in the method 6 may be modified, replaced, or eliminated without departure from the spirit and scope of the present disclosure. For example, when step 63 is omitted and the free layer 54 is formed on the tunnel barrier layer 53 in step 64, the MTJ element 5 shown in FIG. 6 can be obtained. When sequence of steps is adjusted, the MTJ element shown in FIG. 16 can be obtained. In some alternative embodiments, other suitable methods may also be applied for forming the MTJ element 5.

In this disclosure, a MTJ element is provided with at least one dusting layer for enhancing thermal stability and keeping TMR ratio of the MTJ element. The dusting layer interposed between a ferromagnetic layer (e.g., a free layer) and an oxide layer (e.g., a capping layer or a tunnel barrier layer) is considered to act as a barrier layer to prevent diffusion of impurities (e.g., boron) to interfacial regions between the ferromagnetic layer and the oxide layer, so as to induce stronger interfacial PMA between the ferromagnetic layer and the oxide layer, thereby obtaining a MTJ element with a higher interfacial PMA and a higher thermal stability. Furthermore, in the case that the dusting layer is interposed between the free layer and the capping layer, coercive field (Hc) of the MTJ element is significantly enhanced and TMR ratio is kept at the same time, and other magnetic properties (e.g., canting) and electrical properties (e.g., read voltage, write voltage, and RA) are not significantly changed. Additionally, the dusting layer(s) can be suitably introduced in the MTJ element regardless of whether it is designed as a top spin valve configuration or a bottom spin configuration. Therefore, the structure of the MTJ element of the disclosure provides a flexible strategy for MTJ optimization.

In accordance with some embodiments of the present disclosure, a magnetic tunnel junction (MTJ) element includes a reference layer, a tunnel barrier layer, a free layer, and a dusting layer. The reference layer has a fixed magnetic orientation. The tunnel barrier layer is disposed on the reference layer, and includes an insulating material. The free layer has a changeable magnetic orientation, and includes a first surface and a second surface. The second surface is disposed to confront the tunnel barrier layer and opposite to the first surface. The dusting layer is formed on one of the first and second surfaces of the free layer, and includes a non-magnetic metal.

In accordance with some embodiments of the present disclosure, the non-magnetic metal of the dusting layer includes molybdenum (Mo), tungsten (W), or a combination thereof.

In accordance with some embodiments of the present disclosure, the dusting layer is formed on the second surface of the free layer and interposed between the tunnel barrier layer and the free layer, and has a predetermined thickness to permit an interfacial perpendicular magnetic anisotropy (PMA) to be established between the tunnel barrier layer and the free layer.

In accordance with some embodiments of the present disclosure, the predetermined thickness of the dusting layer is greater than 0 Å and less than 3 Å.

In accordance with some embodiments of the present disclosure, the insulating material of the tunnel barrier layer includes oxide, nitride, oxynitride, or combinations thereof.

In accordance with some embodiments of the present disclosure, a magnetic tunnel junction (MTJ) element includes a reference layer, a tunnel barrier layer, a free layer, a capping layer, and a dusting layer. The reference layer has a fixed magnetic orientation. The tunnel barrier layer is disposed on the reference layer, and includes a first insulating material. The free layer has a changeable magnetic orientation, and includes a first surface and a second surface. The second surface is disposed to confront the tunnel barrier layer and opposite to the first surface. The capping layer is disposed on the second surface of the free layer, and includes a second insulating material. The dusting layer is formed on one of the first and second surfaces of the free layer, and includes a first non-magnetic metal.

In accordance with some embodiments of the present disclosure, the dusting layer is formed on the first surface of the free layer and is interposed between the free layer and the capping layer.

In accordance with some embodiments of the present disclosure, the MTJ element further includes an additional dusting layer which is formed on the second surface of the free layer, which is interposed between the tunnel barrier layer and the free layer, and which includes a second non-magnetic metal.

In accordance with some embodiments of the present disclosure, each of the first and second non-magnetic metals independently includes molybdenum (Mo), tungsten (W), or a combination thereof.

In accordance with some embodiments of the present disclosure, the dusting layer has a predetermined thickness to permit an interfacial perpendicular magnetic anisotropy (PMA) to be established between the free layer and the capping layer. The additional dusting layer has a predetermined thickness to permit an interfacial PMA to be established between the tunnel barrier layer and the free layer.

In accordance with some embodiments of the present disclosure, the predetermined thickness of each of the dusting layer and the additional dusting layer is greater than 0 Å and less than 3 Å.

In accordance with some embodiments of the present disclosure, each of the first and second insulating materials independently includes metal oxide, metal nitride, metal oxynitride, or combinations thereof.

In accordance with some embodiments of the present disclosure, a method for manufacturing a magnetic tunnel junction (MTJ) element includes: forming a tunnel barrier layer on a reference layer which has a fixed magnetic orientation, the tunnel barrier layer including a first insulating material; forming a free layer on the tunnel barrier layer, the free layer having a changeable magnetic orientation; and forming a dusting layer to be in contact with the free layer, the dusting layer including a first non-magnetic metal.

In accordance with some embodiments of the present disclosure, the dusting layer is interposed between the tunnel barrier layer and the free layer.

In accordance with some embodiments of the present disclosure, the method further includes forming a capping layer on the free layer. The capping layer includes a second insulating material. The dusting layer is interposed between the free layer and the capping layer.

In accordance with some embodiments of the present disclosure, each of the first and second insulating materials independently includes metal oxide, metal nitride, metal oxynitride, or combinations thereof.

In accordance with some embodiments of the present disclosure, the method further includes forming an additional dusting layer between the tunnel barrier layer and the free layer. The additional dusting layer includes a second non-magnetic metal.

In accordance with some embodiments of the present disclosure, each of the first and second non-magnetic metals independently includes molybdenum (Mo), tungsten (W), or a combination thereof.

In accordance with some embodiments of the present disclosure, the dusting layer has a predetermined thickness to permit an interfacial perpendicular magnetic anisotropy (PMA) to be established between the free layer and the capping layer. The additional dusting layer has a predetermined thickness to permit an interfacial PMA to be established between the tunnel barrier layer and the free layer.

In accordance with some embodiments of the present disclosure, the dusting layer is formed by physical vapor deposition.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A magnetic tunnel junction (MTJ) element, comprising:
a reference layer with a fixed magnetic orientation;
a tunnel barrier layer disposed on the reference layer, and including an insulating material;
a free layer having a changeable magnetic orientation, and including a first surface and a second surface, the second surface being disposed to confront the tunnel barrier layer and opposite to the first surface; and
a dusting layer formed on one of the first and second surfaces of the free layer, and including a non-magnetic metal.

2. The MTJ element of claim 1, wherein the non-magnetic metal of the dusting layer includes molybdenum (Mo), tungsten (W), or a combination thereof.

3. The MTJ element of claim 1, wherein the dusting layer is formed on the second surface (542) of the free layer and interposed between the tunnel barrier layer and the free layer, and has a predetermined thickness to permit an interfacial perpendicular magnetic anisotropy (PMA) to be established between the tunnel barrier layer and the free layer.

4. The MTJ element of claim 3, wherein the predetermined thickness of the dusting layer is greater than 0 Å and less than 3 Å.

5. The MTJ element of claim 1, wherein the insulating material of the tunnel barrier layer includes oxide, nitride, oxynitride, or combinations thereof.

6. A magnetic tunnel junction (MTJ) element, comprising:
a reference layer with a fixed magnetic orientation;
a tunnel barrier layer disposed on the reference layer, and including a first insulating material;
a free layer having a changeable magnetic orientation, and including a first surface and a second surface, the second surface being disposed to confront the tunnel barrier layer and opposite to the first surface;
a capping layer disposed on the second surface of the free layer, and including a second insulating material; and
a dusting layer formed on one of the first and second surfaces of the free layer, and including a first non-magnetic metal.

7. The MTJ element of claim 6, wherein the dusting layer is formed on the first surface of the free layer and is interposed between the free layer and the capping layer.

8. The MTJ element of claim 7, further comprising an additional dusting layer which is formed on the second surface of the free layer, which is interposed between the tunnel barrier layer and the free layer, and which includes a second non-magnetic metal.

9. The MTJ element of claim 8, wherein each of the first and second non-magnetic metals independently includes molybdenum (Mo), tungsten (W), or a combination thereof.

10. The MTJ element of claim 8, wherein the dusting layer has a predetermined thickness to permit an interfacial perpendicular magnetic anisotropy (PMA) to be established between the free layer and the capping layer, the additional dusting layer having a predetermined thickness to permit an interfacial PMA to be established between the tunnel barrier layer and the free layer.

11. The MTJ element of claim 10, wherein the predetermined thickness of each of the dusting layer and the additional dusting layer is greater than 0 Å and less than 3 Å.

12. The MTJ element of claim 6, wherein each of the first and second insulating materials independently includes metal oxide, metal nitride, metal oxynitride, or combinations thereof.

13. A method for manufacturing a magnetic tunnel junction (MTJ) element, comprising:
forming a tunnel barrier layer on a reference layer which has a fixed magnetic orientation, the tunnel barrier layer including a first insulating material;
forming a free layer on the tunnel barrier layer, the free layer having a changeable magnetic orientation; and
forming a dusting layer to be in contact with the free layer, the dusting layer including a first non-magnetic metal.

14. The method of claim 13, wherein the dusting layer is interposed between the tunnel barrier layer and the free layer.

15. The method of claim 13, further comprising
forming a capping layer on the free layer, the capping layer including a second insulating material, the dusting layer being interposed between the free layer and the capping layer.

16. The method of claim 15, wherein each of the first and second insulating materials independently includes metal oxide, metal nitride, metal oxynitride, or combinations thereof.

17. The method of claim 15, further comprising
forming an additional dusting layer between the tunnel barrier layer and the free layer, the additional dusting layer including a second non-magnetic metal.

18. The method of claim 17, wherein each of the first and second non-magnetic metals independently includes molybdenum (Mo), tungsten (W), or a combination thereof.

19. The method of claim 17, wherein the dusting layer has a predetermined thickness to permit an interfacial perpendicular magnetic anisotropy (PMA) to be established between the free layer and the capping layer, the additional dusting layer having a predetermined thickness to permit an interfacial PMA to be established between the tunnel barrier layer and the free layer.

20. The method of claim 13, wherein the dusting layer is formed by physical vapor deposition.
